(19) United States
(12) Patent Application Publication
(10) Pub. No.: US 2023/0324797 A1
(43) Pub. Date: Oct. 12, 2023

(54) POSITIVE RESIST COMPOSITION FOR EXTREME ULTRAVIOLET LITHOGRAPHY AND RESIST PATTERN FORMATION KIT FOR EXTREME ULTRAVIOLET LITHOGRAPHY

(71) Applicant: ZEON CORPORATION, Chiyoda-ku, Tokyo (JP)

(72) Inventor: Manabu HOSHINO, Chiyoda-ku, Tokyo (JP)

(73) Assignee: ZEON CORPORATION, Chiyoda-ku, Tokyo (JP)

(21) Appl. No.: 18/044,378

(22) PCT Filed: Sep. 15, 2021
(86) PCT No.: PCT/JP2021/033993

§ 371 Date: Mar. 8, 2023

(30) Foreign Application Priority Data
Sep. 30, 2020 (JP) 2020-166334
Oct. 14, 2020 (JP) 2020-173583
Dec. 22, 2020 (JP) 2020-212884

(51) Int. Cl. G03F 7/039; C08F 212/08; C08F 220/24

(52) U.S. Cl. CPC G03F 7/039; G03F 7/2004; C08F 220/24; C08F 212/08

(57) ABSTRACT

Provided is a positive resist composition that can be used for efficiently forming a fine resist pattern with high resolution in an EUV lithography technique. The positive resist composition for extreme ultraviolet lithography contains a copolymer having a weight-average molecular weight of more than 100,000 and including monomer units (A) and (B) represented by formulae (I) and (II), shown below. In formula (I), X is a halogen atom, etc., L is a single bond or divalent linking group, and Ar is an optionally substituted aromatic ring group. In formula (II), R¹ is an alkyl group, R² is an alkyl group, halogen atom, haloalkyl group, hydroxyl group, carboxyl group, or halogenated carboxyl group, p is an integer of not less than 0 and not more than 5, and in a case in which more than one R² is present, each R² may be the same or different.

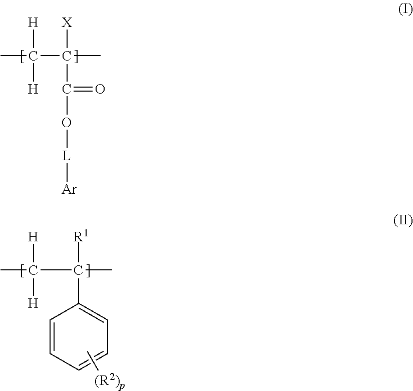

### TECHNICAL FIELD

The present disclosure relates to a positive resist composition for extreme ultraviolet lithography and a resist pattern formation kit for extreme ultraviolet lithography.

### BACKGROUND

Copolymers that display increased solubility in a developer after undergoing main chain scission through irradiation with ionizing radiation, such as an electron beam, or short-wavelength light, such as ultraviolet light, are conventionally used as main chain scission-type positive resists in fields such as semiconductor production. (Hereinafter, the term “ionizing radiation or the like” is used to refer collectively to ionizing radiation and short-wavelength light.)

As one specific example, Patent Literature (PTL) 1 discloses, as a main chain scission-type positive resist having excellent sensitivity to ionizing radiation and heat resistance, a positive resist that is formed of a copolymer including a 1-phenyl-1-trifluoromethyl-2,2,2-trifluoroethyl α-chloroacrylate unit and an α-methylstyrene unit.

### CITATION LIST

### Patent Literature

PTL 1: JP2018-154754A

### SUMMARY

### Technical Problem

In recent years, a technique of EUV lithography using extreme ultraviolet light (EUV) has been attracting attention as a technique that enables formation of fine patterns and has a small proximity effect during exposure compared to when an electron beam or the like is used. However, there is still room for improvement in the conventional technique described above in terms of enabling efficient formation of a fine resist pattern with high resolution when using extreme ultraviolet light as a light source for exposure.

Accordingly, an object of the present disclosure is to provide a positive resist composition and a resist pattern formation kit that can be used for efficiently forming a fine resist pattern with high resolution in an EUV lithography technique.

Note that the term “high resolution” as used in the present disclosure means that surface roughness at the surface of an exposed section after development, the occurrence of missing contact holes, and so forth are inhibited and that good evaluation results are achieved for CD (Critical Dimension: value expressing a critical dimension for line width of a resist pattern), LWR (Line Width Roughness: value expressing roughness of line width), LER (Line Edge Roughness: value expressing roughness of line edges), LCDU (Local Critical Dimension Uniformity: local uniformity of a critical dimension), and so forth.

### Solution to Problem

The inventor conducted diligent studies with the aim of achieving the object set forth above. The inventor discovered that it is possible to efficiently form a fine resist pattern with high resolution in an EUV lithography technique by using a copolymer that is formed using specific monomers and that has a weight-average molecular weight within a specific range, and, in this manner, completed the present disclosure.

Specifically, the present disclosure aims to advantageously solve the problem set forth above, and a presently disclosed positive resist composition for extreme ultraviolet lithography comprises a copolymer that has a weight-average molecular weight of more than 100,000 and that includes:
a monomer unit (A) represented by formula (I), shown below,

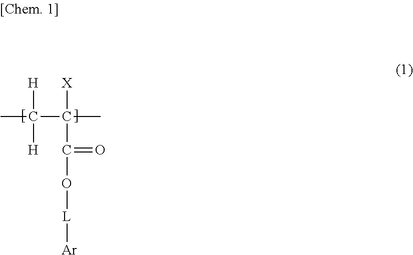

where, in formula (I), X is a halogen atom, a cyano group, an alkylsulfonyl group, an alkoxy group, a nitro group, an acyl group, an alkyl ester group, or a haloalkyl group, L is a single bond or a divalent linking group, and Ar is an optionally substituted aromatic ring group; and
a monomer unit (B) represented by formula (II), shown below,

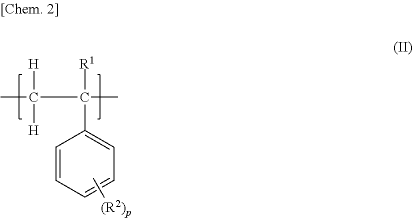

where, in formula (II), R¹ is an alkyl group, R² is an alkyl group, a halogen atom, a haloalkyl group, a hydroxyl group, a carboxyl group, or a halogenated carboxyl group, p is an integer of not less than 0 and not more than 5, and in a case in which more than one R² is present, each R² may be the same or different.

A copolymer that includes the monomer unit (A) and the monomer unit (B) set forth above can be favorably used as a main chain scission-type positive resist. Moreover, when the weight-average molecular weight of a copolymer that includes the monomer unit (A) and the monomer unit (B) is more than 100,000, it is possible to efficiently form a fine resist pattern with high resolution upon use in EUV lithography.

Note that the “weight-average molecular weight” referred to in the present disclosure can be measured as a standard polystyrene-equivalent value by gel permeation chromatography.

In the presently disclosed positive resist composition for extreme ultraviolet lithography, it is preferable that the monomer unit (A) is a 1-phenyl-1-trifluoromethyl-2,2,2-trifluoroethyl α-chloroacrylate unit and the monomer unit (B) is an α-methylstyrene unit or a 4-methyl-α-methylstyrene unit. When the copolymer includes the monomer units set forth above, sensitivity to EUV can be sufficiently improved, and a fine resist pattern can be better formed.

In the presently disclosed positive resist composition for extreme ultraviolet lithography, it is preferable that proportional content of the monomer unit (A) in the copolymer is more than 50 mol % and not more than 60 mol % and proportional content of the monomer unit (B) in the copolymer is not less than 40 mol % and less than 50 mol %. When the copolymer includes the monomer unit (A) and the monomer unit (B) in proportions that are within the ranges set forth above, a fine resist pattern can be more efficiently formed with high resolution upon use in EUV lithography.

In the presently disclosed positive resist composition for extreme ultraviolet lithography, the copolymer preferably has a molecular weight distribution (Mw/Mn) of not less than 1.20 and not more than 1.60.

Note that the “molecular weight distribution” referred to in the present disclosure can be determined by calculating a ratio of the weight-average molecular weight relative to the number-average molecular weight (weight-average molecular weight/number-average molecular weight), and the “number-average molecular weight” can be measured as a standard polystyrene-equivalent value by gel permeation chromatography.

In the presently disclosed positive resist composition for extreme ultraviolet lithography, a proportion of components having a molecular weight of less than 10,000 in the copolymer is preferably less than 1.5%. When the proportion of components having a molecular weight of less than 10,000 is within the range set forth above, a fine resist pattern can be more efficiently formed with high resolution upon use in EUV lithography.

Note that the “proportion of components having a molecular weight of less than 10,000” referred to in the present disclosure can be determined by using a chromatogram obtained through gel permeation chromatography to calculate a proportion of the total area (B) of peaks for components having a molecular weight of less than 10,000 in the chromatogram relative to the total area (A) of peaks in the chromatogram (=(B/A)×100%).

In the presently disclosed positive resist composition for extreme ultraviolet lithography, a proportion of components having a molecular weight of less than 50,000 in the copolymer is preferably less than 30%. When the proportion of components having a molecular weight of less than 50,000 is within the range set forth above, a fine resist pattern can be more efficiently formed with high resolution upon use in EUV lithography.

Note that the “proportion of components having a molecular weight of less than 50,000” referred to in the present disclosure can be determined by using a chromatogram obtained through gel permeation chromatography to calculate a proportion of the total area (C) of peaks for components having a molecular weight of less than 50,000 in the chromatogram relative to the total area (A) of peaks in the chromatogram (=(C/A)×100%).

In the presently disclosed positive resist composition for extreme ultraviolet lithography, a proportion of components having a molecular weight of less than 100,000 in the copolymer is preferably less than 70%. When the proportion of components having a molecular weight of less than 100,000 is within the range set forth above, a fine resist pattern can be more efficiently formed with high resolution upon use in EUV lithography.

Note that the “proportion of components having a molecular weight of less than 100,000” referred to in the present disclosure can be determined by using a chromatogram obtained through gel permeation chromatography to calculate a proportion of the total area (D) of peaks for components having a molecular weight of less than 100,000 in the chromatogram relative to the total area (A) of peaks in the chromatogram (=(D/A)×100%).

In the presently disclosed positive resist composition for extreme ultraviolet lithography, a proportion of components having a molecular weight of more than 200,000 in the copolymer is preferably more than 8.0%. When the proportion of components having a molecular weight of more than 200,000 is within the range set forth above, a fine resist pattern can be more efficiently formed with high resolution upon use in EUV lithography.

Note that the “proportion of components having a molecular weight of more than 200,000” referred to in the present disclosure can be determined by using a chromatogram obtained through gel permeation chromatography to calculate a proportion of the total area (E) of peaks for components having a molecular weight of more than 200,000 in the chromatogram relative to the total area (A) of peaks in the chromatogram (=(E/A)×100%).

Moreover, the present disclosure aims to advantageously solve the problem set forth above, and a presently disclosed resist pattern formation kit for extreme ultraviolet lithography comprises: any one of the positive resist compositions for extreme ultraviolet lithography set forth above; and a developer. By using a resist pattern formation kit including the positive resist composition for extreme ultraviolet lithography set forth above and a developer in EUV lithography, it is possible to efficiently form a fine resist pattern with high resolution.

In the presently disclosed resist pattern formation kit for extreme ultraviolet lithography, the developer is preferably an alcohol, and more preferably an alcohol having a carbon number of not less than 2 and not more than 6. By using an alcohol, and preferably an alcohol having a carbon number of not less than 2 and not more than 6 as the developer, it is possible to more efficiently form a fine resist pattern with high resolution by EUV lithography.

### Advantageous Effect

According to the present disclosure, it is possible to efficiently form a fine resist pattern with high resolution in an EUV lithography technique.

### DETAILED DESCRIPTION

The following provides a detailed description of embodiments of the present disclosure.

Note that the term “optionally substituted” as used in the present disclosure means “unsubstituted or having one or more substituents”.

The presently disclosed positive resist composition for EUV lithography is used for forming a resist film in formation of a resist pattern using extreme ultraviolet light, which enables formation of a fine pattern and has a small proximity effect during exposure compared to an electron beam or the like. Moreover, the presently disclosed resist pattern formation kit for EUV lithography contains the presently disclosed positive resist composition for EUV lithography and can suitably be used, for example, in formation of a resist pattern using extreme ultraviolet light in a production process of a printed board such as a build-up board.

(Positive Resist Composition for EUV Lithography)

The presently disclosed positive resist composition for EUV lithography contains a specific copolymer that is described in detail below and normally also contains a solvent. The positive resist composition for EUV lithography may optionally further contain known additives that can be used in resist compositions.

As a result of the presently disclosed positive resist composition for EUV lithography containing the specific copolymer as a positive resist, it is possible to efficiently form a fine resist pattern with high resolution by using a resist film that is obtained through application and drying of this positive resist composition on a substrate.

Note that although the presently disclosed positive resist composition for EUV lithography may also contain a polymer other than the specific copolymer as a positive resist, the presently disclosed positive resist composition for EUV lithography normally only contains the specific copolymer as a positive resist.

<Copolymer>

The copolymer contained in the presently disclosed positive resist composition is required to include specific monomer units (A) and (B) and have a weight-average molecular weight of more than 100,000.

Note that although the copolymer used herein may also include any monomer units other than the monomer unit (A) and the monomer unit (B), the proportion constituted by the monomer unit (A) and the monomer unit (B) among all monomer units of the copolymer is, in total, preferably 90 mol % or more, and more preferably 100 mol % (i.e., the copolymer more preferably only includes the monomer unit (A) and the monomer unit (B)).

[Monomer unit (A)]

The monomer unit (A) is a structural unit that is represented by formula (I), shown below,

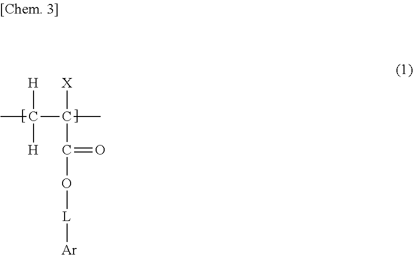

(in formula (I), X is a halogen atom, a cyano group, an alkylsulfonyl group, an alkoxy group, a nitro group, an acyl group, an alkyl ester group, or a haloalkyl group, L is a single bond or a divalent linking group, and Ar is an optionally substituted aromatic ring group) and that is derived from a monomer (a) represented by formula (III), shown below,

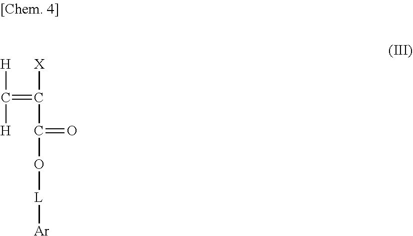

(in formula (III), X, L, and Ar are the same as in formula (I)).

The halogen atom that can constitute X in formula (I) and formula (III) may be a chlorine atom, a fluorine atom, a bromine atom, an iodine atom, an astatine atom, or the like, for example. The alkylsulfonyl group that can constitute X in formula (I) and formula (III) may be a methylsulfonyl group, an ethylsulfonyl group, or the like, for example. The alkoxy group that can constitute X in formula (I) and formula (III) may be a methoxy group, an ethoxy group, a propoxy group, or the like, for example. The acyl group that can constitute X in formula (I) and formula (III) may be a formyl group, an acetyl group, a propionyl group, or the like. The alkyl ester group that can constitute X in formula (I) and formula (III) may be a methyl ester group, an ethyl ester group, or the like. The haloalkyl group that can constitute X in formula (I) and formula (III) may be a halomethyl group in which the number of halogen atoms is not less than 1 and not more than 3, or the like, for example.

Of these examples, a halogen atom is preferable as X from a viewpoint of efficiently obtaining a copolymer that is useful as a main chain scission-type positive resist, and a chlorine atom is more preferable as X.

The divalent linking group that can constitute L in formula (I) and formula (III) may be an optionally substituted alkylene group, an optionally substituted alkenylene group, or the like, for example, without any specific limitations.

The alkylene group of the optionally substituted alkylene group may be a chain alkylene group such as a methylene group, an ethylene group, a propylene group, an n-butylene group, or an isobutylene group or a cyclic alkylene group such as a 1,4-cyclohexylene group, for example, without any specific limitations. Of these examples, a chain alkylene group having a carbon number of 1 to 6 such as a methylene group, an ethylene group, a propylene group, an n-butylene group, or an isobutylene group is preferable as the alkylene group, a linear alkylene group having a carbon number of 1 to 6 such as a methylene group, an ethylene group, a propylene group, or an n-butylene group is more preferable as the alkylene group, and a linear alkylene group having a carbon number of 1 to 3 such as a methylene group, an ethylene group, or a propylene group is even more preferable as the alkylene group.

The alkenylene group of the optionally substituted alkenylene group may be a chain alkenylene group such as an ethenylene group, a 2-propenylene group, a 2-butenylene group, or a 3-butenylene group or a cyclic alkenylene group such as a cyclohexenylene group, for example, without any specific limitations. Of these examples, a linear alkenylene group having a carbon number of 2 to 6 such as an ethenylene group, a 2-propenylene group, a 2-butenylene group, or a 3-butenylene group is preferable as the alkenylene group.

Of the examples given above, an optionally substituted alkylene group is preferable as the divalent linking group from a viewpoint of sufficiently improving sensitivity to EUV, with an optionally substituted chain alkylene group having a carbon number of 1 to 6 being more preferable, an optionally substituted linear alkylene group having a carbon number of 1 to 6 being even more preferable, and an optionally substituted linear alkylene group having a carbon number of 1 to 3 being particularly preferable.

Moreover, the divalent linking group that can constitute L in formula (I) and formula (III) preferably includes one or more electron withdrawing groups from a viewpoint of further improving sensitivity to EUV. In particular, in a case in which the divalent linking group is an alkylene group that includes an electron withdrawing group as a substituent or an alkenylene group that includes an electron withdrawing group as a substituent, the electron withdrawing group is preferably bonded to a carbon that is bonded to the oxygen adjacent to the carbonyl carbon in formula (I) and formula (III).

Note that one or more selected from the group consisting of a fluorine atom, a fluoroalkyl group, a cyano group, and a nitro group may, for example, serve as an electron withdrawing group that can sufficiently improve sensitivity to EUV without any specific limitations. The fluoroalkyl group may be a fluoroalkyl group having a carbon number of 1 to 5, for example, without any specific limitations. In particular, the fluoroalkyl group is preferably a perfluoroalkyl group having a carbon number of 1 to 5, and more preferably a trifluoromethyl group.

From a viewpoint of sufficiently improving sensitivity to EUV, L in formula (I) and formula (III) is preferably a methylene group, a cyanomethylene group, a trifluoromethylmethylene group, or a bis(trifluoromethyl)methylene group, and is more preferably a bis(trifluoromethyl)methylene group.

Ar in formula (I) and formula (III) may be an optionally substituted aromatic hydrocarbon ring group or an optionally substituted aromatic heterocyclic group.

The aromatic hydrocarbon ring group may be a benzene ring group, a biphenyl ring group, a naphthalene ring group, an azulene ring group, an anthracene ring group, a phenanthrene ring group, a pyrene ring group, a chrysene ring group, a naphthacene ring group, a triphenylene ring group, an o-terphenyl ring group, an m-terphenyl ring group, a p-terphenyl ring group, an acenaphthene ring group, a coronene ring group, a fluorene ring group, a fluoranthene ring group, a pentacene ring group, a perylene ring group, a pentaphene ring group, a picene ring group, a pyranthrene ring group, or the like, for example, without any specific limitations.

The aromatic heterocyclic group may be a furan ring group, a thiophene ring group, a pyridine ring group, a pyridazine ring group, a pyrimidine ring group, a pyrazine ring group, a triazine ring group, an oxadiazole ring group, a triazole ring group, an imidazole ring group, a pyrazole ring group, a thiazole ring group, an indole ring group, a benzimidazole ring group, a benzothiazole ring group, a benzoxazole ring group, a quinoxaline ring group, a quinazoline ring group, a phthalazine ring group, a benzofuran ring group, a dibenzofuran ring group, a benzothiophene ring group, a dibenzothiophene ring group, a carbazole ring group, or the like, for example, without any specific limitations.

Examples of possible substituents of Ar include, but are not specifically limited to, an alkyl group, a fluorine atom, and a fluoroalkyl group. Examples of alkyl groups that are possible substituents of Ar include chain alkyl groups having a carbon number of 1 to 6 such as a methyl group, an ethyl group, a propyl group, an n-butyl group, and an isobutyl group. Examples of fluoroalkyl groups that are possible substituents of Ar include fluoroalkyl groups having a carbon number of 1 to 5 such as a trifluoromethyl group, a trifluoroethyl group, and a pentafluoropropyl group.

Of the examples given above, an optionally substituted aromatic hydrocarbon ring group is preferable as Ar in formula (I) and formula (III) from a viewpoint of sufficiently improving sensitivity to EUV, with an unsubstituted aromatic hydrocarbon ring group being more preferable, and a benzene ring group (phenyl group) being even more preferable.

Moreover, from a viewpoint of sufficiently improving sensitivity to EUV, the monomer (a) represented by formula (III) described above that can form the monomer unit (A) represented by formula (I) described above is preferably benzyl α-chloroacrylate or 1-phenyl-1-trifluoromethyl-2,2,2-trifluoroethyl α-chloroacrylate, and more preferably 1-phenyl-1-trifluoromethyl-2,2,2-trifluoroethyl α-chloroacrylate. In other words, the copolymer preferably includes either or both of a 1-phenyl-1-trifluoromethyl-2,2,2-trifluoroethyl α-chloroacrylate unit and a benzyl α-chloroacrylate unit, and more preferably includes a 1-phenyl-1-trifluoromethyl-2,2,2-trifluoroethyl α-chloroacrylate unit.

Note that the proportion constituted by the monomer unit (A) among all monomer units of the copolymer can be set as not less than 30 mol % and not more than 70 mol %, for example, but is not specifically limited thereto. In particular, the proportion constituted by the monomer unit (A) is preferably 50 mol % or more, more preferably more than 50 mol %, and even more preferably 52 mol % or more, and is preferably 60 mol % or less, more preferably 55 mol % or less, and even more preferably 54 mol % or less. When the proportion constituted by the monomer unit (A) is within any of the ranges set forth above, a fine resist pattern can be more efficiently formed with high resolution upon use in EUV lithography.

[Monomer Unit (B)]

The monomer unit (B) is a structural unit that is represented by formula (II), shown below,

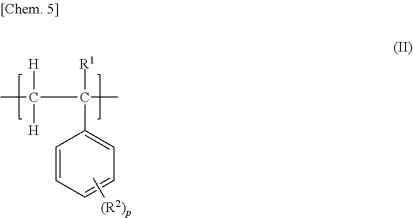

(in formula (II), R¹ is an alkyl group, R² is an alkyl group, a halogen atom, a haloalkyl group, a hydroxyl group, a carboxyl group, or a halogenated carboxyl group (—C(═O)—X; X is a halogen atom), p is an integer of not less than 0 and not more than 5, and in a case in which more than one R² is present, each R² may be the same or different) and that is derived from a monomer (b) represented by formula (IV), shown below,

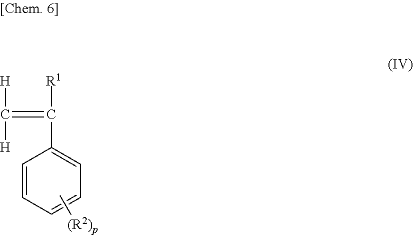

(in formula (IV), R¹, R², and p are the same as in formula (II)).

The alkyl group that can constitute R¹ and R² in formula (II) and formula (IV) may be an unsubstituted alkyl group having a carbon number of 1 to 5, for example, without any specific limitations. In particular, the alkyl group that can constitute R¹ and R² is preferably a methyl group or an ethyl group.

The halogen atom that can constitute R² in formula (II) and formula (IV) may be a fluorine atom, a chlorine atom, a bromine atom, an iodine atom, or the like, without any specific limitations. Of these examples, a fluorine atom is preferable as the halogen atom.

The haloalkyl group that can constitute R² in formula (II) and formula (IV) may be a fluoroalkyl group having a carbon number of 1 to 5, for example, without any specific limitations. In particular, the haloalkyl group is preferably a perfluoroalkyl group having a carbon number of 1 to 5, and more preferably a trifluoromethyl group.

The halogenated carboxyl group that can constitute R² in formula (II) and formula (IV) may be a chlorinated carboxyl group (—C(═O)—Cl), a fluorinated carboxyl group (—C(═O)—F), a brominated carboxyl group (—C(═O)—Br), or the like, for example, without any specific limitations.

From a viewpoint of ease of production of the copolymer and improving main chain scission properties upon irradiation with EUV, 10 in formula (II) and formula (IV) is preferably an alkyl group having a carbon number of 1 to 5, and more preferably a methyl group.

Moreover, from a viewpoint of ease of production of the copolymer and improving main chain scission properties upon irradiation with EUV, p in formula (II) and formula (IV) is preferably 0 or 1.

Furthermore, in a case in which p in formula (II) and formula (IV) is any one of 1 to 5, R² in formula (II) and formula (IV) is preferably an alkyl group having a carbon number of 1 to 5, and more preferably a methyl group.

Examples of the monomer (b) represented by formula (IV) described above that can form the monomer unit (B) represented by formula (II) described above include, but are not specifically limited to, α-methylstyrene and derivatives thereof, such as (b-1) to (b-12), shown below.

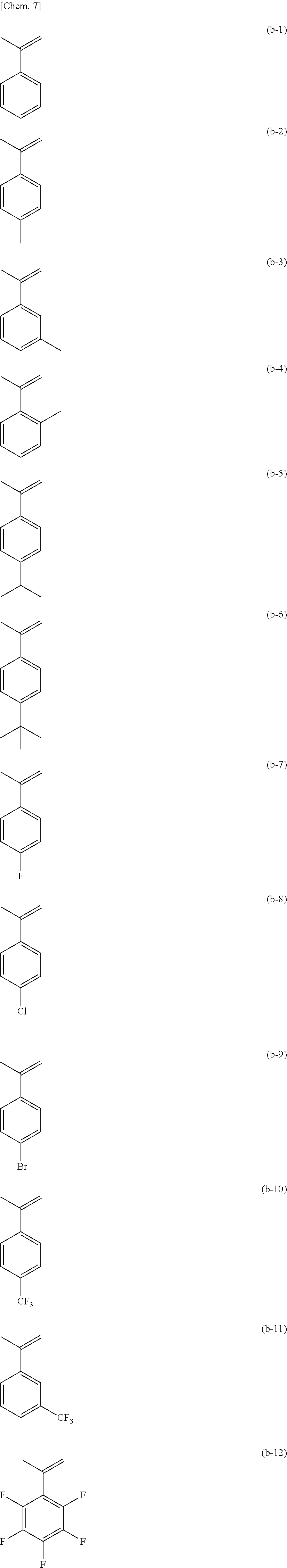

Note that the monomer unit (B) is preferably a structural unit derived from α-methylstyrene or 4-methyl-α-methylstyrene from a viewpoint of ease of production of the copolymer and improving main chain scission properties upon irradiation with EUV. In other words, the copolymer preferably includes an α-methylstyrene unit or a 4-methyl-α-methylstyrene unit.

Note that the proportion constituted by the monomer unit (B) among all monomer units of the copolymer can be set as not less than 30 mol % and not more than 70 mol %, for example, but is not specifically limited thereto. In particular, the proportion constituted by the monomer unit (B) is preferably 40 mol % or more, more preferably 45 mol % or more, and even more preferably 46 mol % or more, and is preferably 50 mol % or less, more preferably less than 50 mol %, and even more preferably 48 mol % or less. When the proportion constituted by the monomer unit (B) is within any of the ranges set forth above, a fine resist pattern can be more efficiently formed with high resolution upon use in EUV lithography.

[Properties of Copolymer]

The weight-average molecular weight (Mw) of the copolymer is required to be more than 100,000. Moreover, the weight-average molecular weight of the copolymer is preferably 110,000 or more, more preferably 150,000 or more, and even more preferably 200,000 or more. When the weight-average molecular weight of the copolymer is within any of the ranges set forth above, a fine resist pattern can be efficiently formed with high resolution upon use in EUV lithography.

Although no specific limitations are placed on the upper limit for the weight-average molecular weight of the copolymer, the weight-average molecular weight of the copolymer is preferably 500,000 or less, and more preferably 210,000 or less from a viewpoint of limiting complication of filtration during production of the positive resist composition.

The number-average molecular weight (Mn) of the copolymer is preferably 70,000 or more, more preferably 110,000 or more, and even more preferably 130,000 or more, and is preferably 400,000 or less, more preferably 300,000 or less, and even more preferably 140,000 or less. When the number-average molecular weight of the copolymer is not less than any of the lower limits set forth above, a fine resist pattern can be efficiently formed with high resolution upon use in EUV lithography. Moreover, when the number-average molecular weight of the copolymer is not more than any of the upper limits set forth above, production of the positive resist composition is easy.

The molecular weight distribution (Mw/Mn) of the copolymer is preferably 1.20 or more, more preferably 1.25 or more, and even more preferably 1.30 or more, and is preferably 2.00 or less, more preferably 1.90 or less, even more preferably 1.60 or less, further preferably 1.50 or less, and particularly preferably 1.40 or less.

Moreover, from a viewpoint of more efficiently forming a fine resist pattern with high resolution upon use of the positive resist composition in EUV lithography, the copolymer preferably satisfies at least one of the following (1) to (4), and more preferably satisfies all of (1) to (4).
(1) The proportion of components having a molecular weight of less than 10,000 is less than 1.5%, preferably 1.3% or less, more preferably 0.5% or less, even more preferably 0.25% or less, further preferably 0.15% or less, and particularly preferably 0.08% or less. On the other hand, the proportion of components having a molecular weight of less than 10,000 is 0.0001% or more, for example, and may be 0.0003% or more, but is not specifically limited thereto.
(2) The proportion of components having a molecular weight of less than 50,000 is less than 30%, preferably 20% or less, more preferably 5% or less, even more preferably 1% or less, and particularly preferably 0.4% or less. On the other hand, the proportion of components having a molecular weight of less than 50,000 is 0.01% or more, for example, and may be 0.05% or more, but is not specifically limited thereto.
(3) The proportion of components having a molecular weight of less than 100,000 is less than 70%, preferably 65% or less, more preferably 30% or less, even more preferably 10% or less, further preferably 5% or less, and particularly preferably 2% or less. On the other hand, the proportion of components having a molecular weight of less than 100,000 is 0.1% or more, for example, and may be 0.5% or more, but is not specifically limited thereto.
(4) The proportion of components having a molecular weight of more than 200,000 is more than 8.0%, preferably 30% or more, more preferably 50% or more, even more preferably 60% or more, and particularly preferably 85% or more. On the other hand, the proportion of components having a molecular weight of more than 200,000 is 99% or less, for example, and may be 95% or less, but is not specifically limited thereto.

[Production Method of Copolymer]

The copolymer including the monomer unit (A) and the monomer unit (B) set forth above can be produced, for example, by carrying out polymerization of a monomer composition that contains the monomer (a) and the monomer (b), and then collecting and optionally purifying the resultant copolymer.

The chemical composition, molecular weight distribution, weight-average molecular weight, and number-average molecular weight of the copolymer can be adjusted by altering the polymerization method, the polymerization conditions (for example, polymerization temperature, polymerization time, and type and amount of polymerization initiator), and the purification conditions. In one specific example, the weight-average molecular weight and the number-average molecular weight can be increased by lowering the polymerization temperature. Moreover, the weight-average molecular weight and the number-average molecular weight can be increased by shortening the polymerization time. Furthermore, the molecular weight distribution can be reduced by performing purification.

The monomer composition used in production of the copolymer may be a mixture containing a monomer component that includes the monomer (a) and the monomer (b), an optionally used solvent, an optionally used polymerization initiator, and optionally added additives. Polymerization of the monomer composition may be carried out by a known method such as solution polymerization or emulsion polymerization. In particular, it is preferable to use cyclopentanone, water, or the like as the solvent. Moreover, the amount of polymerization initiator is preferably 0 (zero).

A polymerized product obtained through polymerization of the monomer composition may be used as the copolymer as obtained or may, without any specific limitations, be collected by adding a good solvent such as tetrahydrofuran to a solution containing the polymerized product and subsequently dripping the solution to which the good solvent has been added into a poor solvent such as methanol to coagulate the polymerized product.

The method of purification in a case in which the obtained polymerized product is purified may be a known purification method such as reprecipitation or column chromatography without any specific limitations. Of these purification methods, purification by reprecipitation is preferable.

Note that purification of the polymerized product may be performed repeatedly.

Purification of the polymerized product by reprecipitation is, for example, preferably carried out by dissolving the resultant polymerized product in a good solvent such as tetrahydrofuran, and subsequently dripping the resultant solution into a mixed solvent of a good solvent, such as tetrahydrofuran, and a poor solvent, such as methanol, to cause precipitation of a portion of the polymerized product. When purification is carried out by dripping a solution of the polymerized product into a mixed solvent of a good solvent and a poor solvent in this manner, the molecular weight distribution, weight-average molecular weight, and number-average molecular weight of the resultant copolymer can easily be adjusted by altering the types and/or mixing ratio of the good solvent and the poor solvent. In one specific example, the molecular weight of copolymer that precipitates in the mixed solvent can be increased by increasing the proportion of the good solvent in the mixed solvent.

Also note that in a situation in which the polymerized product is purified by reprecipitation, polymerized product that precipitates in the mixed solvent of the good solvent and the poor solvent may be used as the copolymer, or polymerized product that does not precipitate in the mixed solvent (i.e., polymerized product dissolved in the mixed solvent) may be used as the copolymer, so long as the polymerized product that is used satisfies the desired properties. Polymerized product that does not precipitate in the mixed solvent can be collected from the mixed solvent by a known technique such as concentration to dryness.

<Solvent>

The solvent contained in the positive resist composition for EUV lithography may be any solvent in which the copolymer described above is soluble without any specific limitations. For example, known solvents such as those described in JP5938536B1 can be used. Of such solvents, anisole, propylene glycol monomethyl ether acetate (PGMEA), cyclopentanone, cyclohexanone, or isoamyl acetate is preferable as the solvent from a viewpoint of obtaining a positive resist composition of suitable viscosity and improving coatability of the positive resist composition.

<Production of Positive Resist Composition for EUV Lithography>

The positive resist composition for EUV lithography can be produced by mixing the above-described copolymer, solvent, and known additives that can optionally be used. The method of mixing is not specifically limited, and mixing may be performed by a commonly known method. Moreover, production may be performed by filtering the mixture after mixing of components.

[Filtration]

No specific limitations are placed on the method by which the mixture is filtered. For example, the mixture can be filtered using a filter. The filter is not specifically limited and may, for example, be a filtration membrane based on a fluorocarbon, cellulose, nylon, polyester, hydrocarbon, or the like. In particular, from a viewpoint of effectively preventing impurities such as metals from becoming mixed into the positive resist composition from metal piping or the like that may be used in production of the copolymer, the constituent material of the filter is preferably nylon, polyethylene, polypropylene, a polyfluorocarbon such as polytetrafluoroethylene or Teflon® (Teflon is a registered trademark in Japan, other countries, or both), tetrafluoroethylene-perfluoroalkyl vinyl ether copolymer (PFA), nylon, a composite membrane of polyethylene and nylon, or the like. For example, a filter disclosed in U.S. Pat. No. 6,103,122A may be used as the filter. Moreover, the filter may be a commercially available product such as Zeta Plus® 40Q (Zeta Plus is a registered trademark in Japan, other countries, or both) produced by CUNO Incorporated. Furthermore, the filter may be a filter that contains a strongly cationic or weakly cationic ion exchange resin. The average particle diameter of the ion exchange resin is not specifically limited but is preferably not less than 2 μm and not more than 10 μm. Examples of cation exchange resins that may be used include a sulfonated phenol-formaldehyde condensate, a sulfonated phenol-benzaldehyde condensate, a sulfonated styrene-divinylbenzene copolymer, a sulfonated methacrylic acid-divinylbenzene copolymer, and other types of sulfo or carboxyl group-containing polymers. In the cation exchange resin, H⁺ counter ions, NH₄⁺ counter ions, or alkali metal counter ions such as K⁺ or Na⁺ counter ions are provided. The cation exchange resin preferably includes hydrogen counter ions. One example of such a cation exchange resin is Microlite® PrCH (Microlite is a registered trademark in Japan, other countries, or both) produced by Purolite, which is a sulfonated styrene-divinylbenzene copolymer including H⁺ counter ions. Another example of such a cation exchange resin is commercially available as AMBERLYST® (AMBERLYST is a registered trademark in Japan, other countries, or both) produced by Rohm and Haas Company.

The pore diameter of the filter is preferably 0.001 μm or more, and more preferably 0.005 μm or more, and is preferably 1 μm or less. When the pore diameter of the filter is within any of the ranges set forth above, it is possible to sufficiently prevent impurities such as metals from being mixed into the positive resist composition.

(Resist Pattern Formation Kit for EUV Lithography)

The presently disclosed resist pattern formation kit for EUV lithography contains the positive resist composition for EUV lithography set forth above and a developer and can be used in formation of a resist pattern using an EUV lithography technique. As a result of the presently disclosed resist pattern formation kit for EUV lithography containing the positive resist composition set forth above, the presently disclosed resist pattern formation kit for EUV lithography can efficiently form a fine resist pattern with high resolution upon use in EUV lithography.

<Developer>

The developer that is used in the presently disclosed resist pattern formation kit for EUV lithography is not specifically limited and can be selected as appropriate depending, for example, on properties of the copolymer that is contained in the positive resist composition set forth above. Specifically, in selection of the developer, it is preferable to select a developer that does not dissolve a resist film prior to EUV exposure being performed but that can dissolve an exposed part of a resist film that has undergone exposure. One developer may be used individually, or two or more developers may be used as a mixture in a freely selected ratio.

Examples of developers that can be used include fluorinated solvents such as hydrofluorocarbons (1,1,1,2,3,4,4,5,5,5-decafluoropentane (CF₃CFHCFHCF₂CF₃), 1,1,1,2,2,3,3,4,4,5,5,6,6-tridecafluorohexane, 1,1,1,2,2,3,4,5,5,5-decafluoropentane, 1,1,1,3,3-pentafluorobutane, 1,1,1,2,2,3,3,4,4-nonafluorohexane, etc.), hydrochlorofluorocarbons (2,2-dichloro-1,1,1-trifluoroethane, 1,1-dichloro-1-fluoroethane, 1,1-dichloro-2,2,3,3,3-pentafluoropropane (CF₃CF₂CHCl₂), 1,3-dichloro-1,1,2,2,3-pentafluoropropane (CClF₂CF₂CHClF), etc.), hydrofluoroethers (methyl nonafluorobutyl ether (CF₃CF₂CF₂CF₂OCH₃), methyl nonafluoroisobutyl ether, ethyl nonafluorobutyl ether (CF₃CF₂CF₂CF₂OC₂H₅), ethyl nonafluoroisobutyl ether, perfluorohexyl methyl ether (CF₃CF₂CF(OCH₃)C₃F₇), etc.), and perfluorocarbons (CF₄, C₂F₆, C₃F₈, C₄F₈, C₄F₁₀, C₅F₁₂, C₆F₁₂, C₆F₁₄, C₇F₁₄, C₇F₁₆, C₈F₁₈, C₉F₂₀, etc.); alcohols such as methanol, ethanol, 1-propanol, 2-propanol (isopropyl alcohol), 1-butanol, 2-butanol, 1-pentanol, 2-pentanol, 3-pentanol, and 1-hexanol; acetic acid esters including an alkyl group such as amyl acetate and hexyl acetate; mixtures of a fluorinated solvent and an alcohol; mixtures of a fluorinated solvent and an acetic acid ester including an alkyl group; mixtures of an alcohol and an acetic acid ester including an alkyl group; and mixtures of a fluorinated solvent, an alcohol, and an acetic acid ester including an alkyl group. Of these developers, an alcohol is preferable from a viewpoint of more efficiently forming a fine resist pattern with high resolution by EUV lithography, with an alcohol having a carbon number of not less than 2 and not more than 6 being more preferable, ethanol, isopropyl alcohol, 1-butanol, 2-butanol, 1-pentanol, or 1-hexanol being even more preferable, and isopropyl alcohol being particularly preferable.

<Method of Forming Resist Pattern Using Resist Pattern Formation Kit>

A method of forming a resist pattern using the presently disclosed resist pattern formation kit for EUV lithography may be a method including the following steps, for example, but is not specifically limited thereto.

[Method of Forming Resist Pattern]

The method of forming a resist pattern using the resist pattern formation kit may, for example, include at least a step (resist film formation step) of forming a resist film on a workpiece such as a substrate using the positive resist composition included in the resist pattern formation kit, a step (exposure step) of exposing the resist film with EUV, and a step (development step) of developing the resist film that has been exposed using the developer included in the resist pattern formation kit.

Note that the method of forming a resist pattern using the resist pattern formation kit may include steps other than the resist film formation step, exposure step, and development step described above. More specifically, the method of forming a resist pattern may include a step (lower layer film formation step) of forming a lower layer film on the substrate on which a resist film is to be formed in advance of the resist film formation step. Moreover, the method of forming a resist pattern may further include a step (post exposure bake step) of heating the resist film that has been exposed between the exposure step and the development step. Furthermore, the method of forming a resist pattern may further include a step (rinsing step) of removing the developer after the development step. After a resist pattern has been formed by the method of forming a resist pattern, a step (etching step) of etching the lower layer film and/or the substrate may be performed.

—Substrate—

The substrate on which a resist film can be formed in the method of forming a resist pattern is not specifically limited and may, for example, be a mask blank including a light shielding layer formed on a substrate or a substrate including an electrically insulating layer and copper foil on the electrically insulating layer that is used in production of a printed board or the like.

The material of the substrate may, for example, be an inorganic material such as a metal (silicon, copper, chromium, iron, aluminum, etc.), glass, titanium oxide, silicon dioxide (SiO₂), silica, or mica; a nitride such as SiN; an oxynitride such as SiON; or an organic material such as acrylic, polystyrene, cellulose, cellulose acetate, or phenolic resin. Of these materials, a metal is preferable as the material of the substrate. By using a silicon substrate, a silicon dioxide substrate, or a copper substrate, and preferably a silicon substrate or a silicon dioxide substrate as the substrate, it is possible to form a structure having a cylinder structure.

No specific limitations are placed on the size and shape of the substrate. Note that the surface of the substrate may be smooth or may have a curved or irregular shape, and that a substrate having a flake shape or the like may be used.

Moreover, the surface of the substrate may be subjected to surface treatment as necessary. For example, in the case of a substrate having hydroxyl groups in a surface layer thereof, the substrate can be surface treated using a silane coupling agent that can react with hydroxyl groups. This makes it possible to convert the surface layer of the substrate from hydrophilic to hydrophobic and to increase close adherence between the substrate and a lower layer film or between the substrate and a resist film. The silane coupling agent is not specifically limited but is preferably hexamethyldisilazane.

—Lower Layer Film Formation Step—

In the lower layer film formation step, a lower layer film is formed on the substrate. Through provision of the lower layer film on the substrate, the surface of the substrate is hydrophobized. This can increase affinity of the substrate and a resist film and can increase close adherence between the substrate and the resist film. The lower layer film may be an inorganic lower layer film or an organic lower layer film.

An inorganic lower layer film can be formed by applying an inorganic material onto the substrate and then performing firing or the like of the inorganic material. The inorganic material may be a silicon-based material or the like, for example.

An organic lower layer film can be formed by applying an organic material onto the substrate to form a coating film and then drying the coating film. The organic material is not limited to being a material that is sensitive to light or an electron beam and may be a resist material or resin material that is typically used in the field of semiconductors or the field of liquid crystals, for example. In particular, the organic material is preferably a material that can form an organic lower layer film that can be etched, and particularly dry etched. By using such an organic material, it is possible to etch the organic lower layer film using a pattern formed through processing of a resist film, and to thereby transfer the pattern to the lower layer film and form a lower layer film pattern. In particular, the organic material is preferably a material that can form an organic lower layer film that can be etched by oxygen plasma etching or the like. For example, AL412 produced by Brewer Science, Inc. or the like may be used as an organic material that is used to form an organic lower layer film.

Application of the organic material described above can be performed by spin coating or a conventional and commonly known method using a spinner or the like. The method by which the coating film is dried may be any method that can cause volatilization of solvent contained in the organic material. For example, a method in which baking is performed or the like may be adopted. Although no specific limitations are placed on the baking conditions, the baking temperature is preferably not lower than 80° C. and not higher than 300° C., and more preferably not lower than 200° C. and not higher than 300° C. Moreover, the baking time is preferably 30 seconds or more, and more preferably 60 seconds or more, and is preferably 500 seconds or less, more preferably 400 seconds or less, even more preferably 300 seconds or less, and particularly preferably 180 seconds or less. Furthermore, the thickness of the lower layer film after drying of the coating film is not specifically limited but is preferably not less than 10 nm and not more than 100 nm.

—Resist Film Formation Step—

The positive resist composition that is included in the presently disclosed resist pattern formation kit is used in the resist film formation step.

In the resist film formation step, the positive resist composition is applied onto a workpiece, such as a substrate, that is to be processed using a resist pattern (onto a lower layer film in a case in which a lower layer film has been formed), and the applied positive resist composition is dried to form a resist film.

The application method and the drying method of the positive resist composition can be methods that are typically used in the formation of a resist film without any specific limitations. In particular, the method of drying is preferably heating (prebaking). The prebaking temperature is preferably 100° C. or higher, more preferably 120° C. or higher, and even more preferably 140° C. or higher from a viewpoint of improving film density of the resist film, and is preferably 250° C. or lower, more preferably 220° C. or lower, and even more preferably 200° C. or lower from a viewpoint of reducing change of the molecular weight and molecular weight distribution of the copolymer in the resist film between before and after prebaking. Moreover, the prebaking time is preferably 10 seconds or more, more preferably 20 seconds or more, and even more preferably 30 seconds or more from a viewpoint of improving film density of the resist film formed through prebaking, and is preferably 10 minutes or less, more preferably 5 minutes or less, and more preferably 3 minutes or less from a viewpoint of reducing change of the molecular weight and molecular weight distribution of the copolymer in the resist film between before and after prebaking.

—Exposure Step—

In the exposure step, the resist film formed in the resist film formation step is irradiated with EUV to write a desired pattern.

Note that the wavelength of EUV used for irradiation is not specifically limited and can, for example, be set as not less than 1 nm and not more than nm, and preferably as 13.5 nm.

The EUV irradiation can be performed using a known exposure tool such as an EQ-10M (produced by Energetiq Technology, Inc.) or NXE (produced by ASML).

—Post Exposure Bake Step—

In the optionally performed post exposure bake step, the resist film that has been exposed in the exposure step is heated. By performing the post exposure bake step, it is possible to reduce the surface roughness of a resist pattern.

The heating temperature is preferably 70° C. or higher, more preferably 80° C. or higher, and even more preferably 90° C. or higher, and is preferably 200° C. or lower, more preferably 170° C. or lower, and even more preferably 150° C. or lower. When the heating temperature is within any of the ranges set forth above, clarity of a resist pattern can be increased while also favorably reducing surface roughness of the resist pattern.

The time for which the resist film is heated (heating time) in the post exposure bake step is preferably 10 seconds or more, more preferably 20 seconds or more, and even more preferably 30 seconds or more. When the heating time is 10 seconds or more, clarity of a resist pattern can be increased while also sufficiently reducing surface roughness of the resist pattern. On the other hand, the heating time is preferably 10 minutes or less, more preferably 5 minutes or less, and even more preferably 3 minutes or less, for example, from a viewpoint of production efficiency.

The method by which the resist film is heated in the post exposure bake step is not specifically limited and may, for example, be a method in which the resist film is heated by a hot plate, a method in which the resist film is heated in an oven, or a method in which hot air is blown against the resist film.

—Development Step—

In the development step, the resist film that has been exposed in the exposure step (resist film that has been exposed and heated in a case in which the post exposure bake step is implemented) and the developer that is included in the resist pattern formation kit are brought into contact so as to develop the resist film and form a resist pattern on the workpiece.

The method by which the resist film and the developer are brought into contact may be, but is not specifically limited to, a method using a known technique such as immersion of the resist film in the developer or application of the developer onto the resist film.

The temperature of the developer during development is not specifically limited and can be set as not lower than 21° C. and not higher than 25° C., for example. The development time can be set as not less than 15 seconds and not more than 4 minutes, for example.

By performing development using the developer that is included in the presently disclosed resist pattern formation kit, it is possible to efficiently form a fine resist pattern with high resolution.

—Rinsing Step—

In the rinsing step, the resist film that has been developed in the development step and a rinsing liquid are brought into contact so as to rinse the developed resist film and form a resist pattern on the workpiece.

The method by which the developed resist film and the rinsing liquid are brought into contact may be, but is not specifically limited to, a method using a known technique such as immersion of the resist film in the rinsing liquid or application of the rinsing liquid onto the resist film.

Any rinsing liquid can be used as the rinsing liquid without any specific limitations so long as it can remove resist residue and developer attached to the developed resist film.

The temperature of the rinsing liquid during rinsing is not specifically limited and can be set as not lower than 21° C. and not higher than 25° C., for example. The rinsing time can be set as not less than 5 seconds and not more than 3 minutes, for example.

The developer and rinsing liquid described above may each be filtered prior to use. The filtration method may be a filtration method using a filter such as previously described in the “Production of positive resist composition” section, for example.

—Etching Step—

In the etching step, etching of the lower layer film and/or the substrate is performed using the above-described resist pattern as a mask so as to form a pattern in the lower layer film and/or substrate.

The number of times that etching is performed is not specifically limited and may be once or a plurality of times. Moreover, the etching may be dry etching or wet etching, but is preferably dry etching. The dry etching can be performed using a commonly known dry etching apparatus. An etching gas that is used in the dry etching can be selected as appropriate depending on the element composition of the lower layer film or substrate that is to be etched, for example. Examples of etching gases that may be used include fluorine-based gases such as CHF₃, CF₄, C₂F₆, C₃F₈, and SF₆; chlorine-based gases such as Cl₂ and BCl₃; oxygen-based gases such as O₂, O₃, and H₂O; reducing gases such as H₂, NH₃, CO, CO₂, CH₄, C₂H₂, C₂H₄, C₂H₆, C₃H₄, C₃H₆, C₃H₈, HF, HI, HBr, HCl, NO, NH₃, and BCl₃; and inert gases such as He, N₂, and Ar. One of these gases may be used individually, or two or more of these gases may be used as a mixture. Note that dry etching of an inorganic lower layer film is usually performed using an oxygen-based gas. Moreover, dry etching of a substrate is normally performed using a fluorine-based gas and may suitably be performed using a mixture of a fluorine-based gas and an inert gas.

Lower layer film remaining on the substrate may be removed before etching of the substrate or after etching of the substrate as necessary. In a case in which the lower layer film is removed before etching of the substrate is performed, this lower layer film may be a lower layer film in which a pattern is formed or may be a lower layer film in which a pattern is not formed.

The method by which the lower layer film is removed may, for example, be dry etching such as described above. In the case of an inorganic lower layer film, the lower layer film may be removed by bringing a liquid such as a basic liquid or an acidic liquid, and preferably a basic liquid into contact with the lower layer film. The basic liquid is not specifically limited and may be alkaline hydrogen peroxide aqueous solution or the like, for example. The method by which the lower layer film is removed through wet stripping using alkaline hydrogen peroxide aqueous solution is not specifically limited so long as it is a method in which the lower layer film and alkaline hydrogen peroxide aqueous solution can be brought into contact under heated conditions for a specific time and may, for example, be a method in which the lower layer film is immersed in heated alkaline hydrogen peroxide aqueous solution, a method in which alkaline hydrogen peroxide aqueous solution is sprayed against the lower layer film in a heated environment, or a method in which heated alkaline hydrogen peroxide aqueous solution is applied onto the lower layer film. After any of these methods is performed, the substrate may be washed with water and then dried to thereby obtain a substrate from which the lower layer film has been removed.

The following describes an example of a method of forming a resist pattern using the presently disclosed resist pattern formation kit and also of a method of etching a lower layer film and a substrate using the resist pattern that is formed. Note that the substrate, conditions in each step, and so forth that are adopted in the following example can be the same as the substrate, conditions in each step, and so forth that were previously described, and thus description thereof is omitted below. Also note that the method by which a resist pattern is formed using the presently disclosed resist pattern formation kit is not limited to the method given in the following example.

One example of a method of forming a resist pattern is a method of forming a resist pattern using EUV that includes the previously described lower layer film formation step, resist film formation step, exposure step, development step, and rinsing step. Moreover, one example of an etching method is a method in which a resist pattern formed by the method of forming a resist pattern is used as a mask and that includes an etching step.

Specifically, in the lower layer film formation step, an inorganic material is applied onto a substrate and is fired to form an inorganic lower layer film.

Next, in the resist film formation step, the positive resist composition that is included in the presently disclosed resist pattern formation kit is applied onto the inorganic lower layer film that has been formed in the lower layer film formation step and is dried to form a resist film.

The resist film that is formed in the resist film formation step is then irradiated with EUV in the exposure step so as to write a desired pattern.

Moreover, in the development step, the resist film that has been exposed in the exposure step and the developer that is included in the presently disclosed resist pattern formation kit are brought into contact to develop the resist film and form a resist pattern on the lower layer film.

In the rinsing step, the resist film that has been developed in the development step and a rinsing liquid are brought into contact to rinse the developed resist film.

In the etching step, the resist pattern is used as a mask to etch the lower layer film and thereby form a pattern in the lower layer film.

The lower layer film in which the pattern has been formed is then used as a mask to etch the substrate and thereby form a pattern in the substrate.

### EXAMPLES

The following provides a more specific description of the present disclosure based on examples. However, the present disclosure is not limited to the following examples. In the following description, “%” used to express quantities is by mass, unless otherwise specified.

In the examples and comparative examples, the following methods were used to measure the weight-average molecular weight, number-average molecular weight, and molecular weight distribution of a copolymer, the proportions of components having various molecular weights in a copolymer, the optimal exposure dose, and values for CD, LWR, LER, and LCDU.

<Weight-Average Molecular Weight, Number-Average Molecular Weight, and Molecular Weight Distribution>

The weight-average molecular weight (Mw) and number-average molecular weight (Mn) of a copolymer obtained in each example or comparative example were measured by gel permeation chromatography, and then the molecular weight distribution (Mw/Mn) of the copolymer was calculated. Specifically, the weight-average molecular weight (Mw) and number-average molecular weight (Mn) of the polymer were determined as standard polystyrene-equivalent values with tetrahydrofuran as an eluent solvent using a gel permeation chromatograph (HLC-8220 produced by Tosoh Corporation). The molecular weight distribution (Mw/Mn) was then calculated.

### <Proportions of Components Having Various Molecular Weights in Copolymer>

A gel permeation chromatograph (HLC-8220 produced by Tosoh Corporation) was used to obtain a chromatogram of a copolymer with tetrahydrofuran as an eluent solvent. The total area (A) of peaks, the total area (B) of peaks for components having a molecular weight of less than 10,000, the total area (C) of peaks for components having a molecular weight of less than 50,000, the total area (D) of peaks for components having a molecular weight of less than 100,000, and the total area (E) of peaks for components having a molecular weight of more than 200,000 were determined from the obtained chromatogram. The proportions of components having various molecular weights were calculated using the following formulae.

Proportion of components having molecular weight of less than 10,000(%)=(B/A)×100

Proportion of components having molecular weight of less than 50,000(%)=(C/A)×100

Proportion of components having molecular weight of less than 100,000(%)=(D/A)×100

Proportion of components having molecular weight of more than 200,000(%)=(E/A)×100

<Optimal exposure dose (Eₒₚ)>

The optimal exposure dose (Eₒₚ) was determined as an optimal point from values for CD, LER, and LWR through swinging of focus and exposure dose.

### <CD, LWR, LER, and LCDU>

A high-resolution FEB measurement apparatus (CG5000 produced by Hitachi High-Tech Corporation) and analysis software (Design Metrology System produced by Hitachi High-Tech Corporation) were used to measure and calculate CD, LWR, LER, and LCDU for a resist pattern formed in each example or comparative example.

A value for CD that is within a range of the half-pitch (hp) or contact hole±5 nm and low values for LWR, LER, and LCDU indicate that the resist pattern has high resolution.

### Example 1

<Production of copolymer>
[Synthesis of polymerized product]

A glass ampoule in which a stirrer had been placed was charged with a monomer composition containing 3.00 g of 1-phenyl-1-trifluoromethyl-2,2,2-trifluoroethyl α-chloroacrylate as a monomer (a), 2.493 g of α-methylstyrene as a monomer (b), and 2.833 g of cyclopentanone as a solvent. The ampoule was tightly sealed and oxygen was removed from the system through 10 repetitions of pressurization and depressurization with nitrogen gas.

The system was then heated to 50° C. and a reaction was carried out for hours. Next, 10 g of tetrahydrofuran was added to the system and then the resultant solution was added dropwise to 300 mL of methanol to cause precipitation of a polymerized product. Thereafter, the polymerized product that had precipitated was collected by filtration. Note that the obtained polymerized product was a copolymer comprising 50 mol % of α-methylstyrene units and 50 mol % of 1-phenyl-1-trifluoromethyl-2,2,2-trifluoroethyl α-chloroacrylate units.

[Purification of polymerized product]

The polymerized product that had been collected by filtration was subsequently dissolved in 10 g of tetrahydrofuran (THF) and then the resultant solution was dripped into 100 g of a mixed solvent of THF and methanol (MeOH) (THF:MeOH (mass ratio)=27:73) to cause precipitation of a white coagulated material (copolymer comprising α-methylstyrene units and 1-phenyl-1-trifluoromethyl-2,2,2-trifluoroethyl α-chloroacrylate units). Thereafter, the solution containing the precipitated copolymer was filtered using a Kiriyama funnel to obtain a white copolymer (copolymer comprising 50 mol % of α-methylstyrene units (AMS units) and 50 mol % of 1-phenyl-1-trifluoromethyl-2,2,2-trifluoroethyl α-chloroacrylate units (ACAFPh units)).

The weight-average molecular weight, number-average molecular weight, and molecular weight distribution of the obtained copolymer were measured. The results are shown in Table 1.

### <Production of Positive Resist Composition>

The obtained copolymer was dissolved in isoamyl acetate as a solvent to produce a resist solution (positive resist composition) having a copolymer concentration of 11 mass %.

### <Formation of Resist Pattern>

A spin coater (MS-A150 produced by Mikasa Co., Ltd.) was used to apply AL412 (produced by Brewer Science, Inc.) as a lower layer film onto a silicon wafer of 4 inches in diameter. The applied AL412 was heated for 1 minute by a hot plate having a temperature of 205° C. to form a lower layer film of 20 nm in thickness on the silicon wafer. Thereafter, the positive resist composition that had been obtained was applied onto this lower layer film. The applied positive resist composition was heated for 3 minutes by a hot plate having a temperature of 150° C. to form a resist film of 33 nm or 50 nm in thickness on the silicon wafer. The resist film was then exposed with the optimal exposure dose (Eₒₚ) using an EUV lithography tool (TWINSCAN NXE:3400B produced by ASML) to write a pattern. Isopropyl alcohol (IPA) was then used as a developer to perform 30 seconds of development treatment at a temperature of 23° C. to form a resist pattern. Lines (non-exposed regions) and spaces (exposed regions) of the resist pattern were set as lines and spaces of 16 nm each (i.e., the half-pitch (hp) was 16 nm).

The obtained resist pattern was used to measure CD, LWR, and LER. The results are shown in Table 1.

### Example 2

Production of a copolymer, production of a positive resist composition, and formation of a resist pattern were performed in the same way as in Example 1 with the exception that a reaction was performed for 80 hours at a temperature of 30° C. in synthesis of the polymerized product and that the chemical composition (THF:MeOH (mass ratio)) of the mixed solvent used in purification of the polymerized product was set as 29:71. Various evaluations were performed in the same way as in Example 1. The results are shown in Table 1.

### Example 3

Production of a copolymer, production of a positive resist composition, and formation of a resist pattern were performed in the same way as in Example 1 with the exception that the copolymer was produced as described below. Various evaluations were performed in the same way as in Example 1. The results are shown in Table 1.

### <Production of Copolymer>

### [Production of 18% Solid Content Aqueous Solution of Partially Hydrogenated Tallow Fatty Acid Potassium Soap]

After preparing 100 g of deionized water and then heating this deionized water to 70° C. under stirring, 8.40 g of potassium hydroxide (49% aqueous solution) was added thereto. Next, 19.6 g of HARDENED TALLOW FATTY ACID 45° HFA (produced by NOF Corporation) was added at an addition rate of 1.28 g/min, and then 0.126 g of potassium silicate was added. At least 2 hours of stirring was performed at 80° C. to yield an 18% solid content aqueous solution of partially hydrogenated tallow fatty acid potassium soap.

### [Synthesis of Polymerized Product]

A glass ampoule in which a stirrer had been placed was charged with 3.00 g of 1-phenyl-1-trifluoromethyl-2,2,2-trifluoroethyl α-chloroacrylate as a monomer (a) and 2.712 g of α-methylstyrene as a monomer (b). In addition, an aqueous solution obtained by adding 6.771 g of deionized water to 0.5463 g of the 18% solid content aqueous solution of partially hydrogenated tallow fatty acid potassium soap produced as described above was added into the same ampoule to obtain a monomer composition, and then the ampoule was tightly sealed and oxygen was removed from the system through 10 repetitions of pressurization and depressurization with nitrogen gas.

The system was then heated to 40° C. and a polymerization reaction was carried out for 11 hours. Next, 10 g of tetrahydrofuran was added to the system and then the resultant solution was dripped into 300 mL of methanol to cause precipitation of a polymerized product. Thereafter, the polymerized product that had precipitated was collected by filtration. Note that the obtained polymerized product was a copolymer comprising 50 mol % of α-methylstyrene units and 50 mol % of 1-phenyl-1-trifluoromethyl-2,2,2-trifluoroethyl α-chloroacrylate units.

### [Purification of Polymerized Product]

The polymerized product that had been collected by filtration was subsequently dissolved in 10 g of tetrahydrofuran (THF) and then the resultant solution was dripped into 100 g of a mixed solvent of THF and methanol (MeOH) (THF:MeOH (mass ratio)=35:65) to cause precipitation of a white coagulated material (copolymer comprising α-methylstyrene units and 1-phenyl-1-trifluoromethyl-2,2,2-trifluoroethyl α-chloroacrylate units). Thereafter, the solution containing the precipitated copolymer was filtered using a Kiriyama funnel to obtain a white copolymer (copolymer comprising 50 mol % of α-methylstyrene units and 50 mol % of 1-phenyl-1-trifluoromethyl-2,2,2-trifluoroethyl α-chloroacrylate units).

The weight-average molecular weight, number-average molecular weight, and molecular weight distribution of the obtained copolymer were measured. The results are shown in Table 1.

### Example 4

Production of a copolymer, production of a positive resist composition, and formation of a resist pattern were performed in the same way as in Example 3 with the exception that ethanol (EtOH) was used as a developer in formation of the resist pattern. Various evaluations were performed in the same way as in Example 1. The results are shown in Table 1.

### Example 5

Production of a copolymer, production of a positive resist composition, and formation of a resist pattern were performed in the same way as in Example 3 with the exception that 3.034 g of 4-methyl-α-methylstyrene (4-isopropenyltoluene) was used instead of α-methylstyrene and a reaction was performed for 6 hours at a temperature of 50° C. in synthesis of the polymerized product and that the chemical composition (THF:MeOH (mass ratio)) of the mixed solvent used in purification of the polymerized product was set as 30:70. Various evaluations were performed in the same way as in Example 1. The results are shown in Table 1.

### Example 6

Production of a copolymer, production of a positive resist composition, and formation of a resist pattern were performed in the same way as in Example 3 with the exception that 3.034 g of 4-methyl-α-methylstyrene (4-isopropenyltoluene) was used instead of α-methylstyrene in synthesis of the polymerized product and that the chemical composition (THF:MeOH (mass ratio)) of the mixed solvent used in purification of the polymerized product was set as 33:67. Various evaluations were performed in the same way as in Example 1. The results are shown in Table 1.

### Examples 7 to 9

Production of a copolymer, production of a positive resist composition, and formation of a resist pattern were performed in the same way as in Example 1 with the exception that the amount of α-methylstyrene was set as 2.132 g (Example 7), 1.599 g (Example 8), or 1.066 g (Example 9), the amount of cyclopentanone was set as 2.199 g (Example 7), 1.971 g (Example 8), or 1.743 g (Example 9), and a reaction was performed for 50 hours at a temperature of 30° C. in synthesis of the polymerized product and that the chemical composition (THF:MeOH (mass ratio)) of the mixed solvent used in purification of the polymerized product was set as 30:70. Various evaluations were performed in the same way as in Example 1. The results are shown in Table 1.

### Example 10

Production of a copolymer, production of a positive resist composition, and formation of a resist pattern were performed in the same way as in Example 9 with the exception that ethanol was used as a developer in formation of the resist pattern. Various evaluations were performed in the same way as in Example 1. The results are shown in Table 1.

### Example 11

Production of a copolymer, production of a positive resist composition, and formation of a resist pattern were performed in the same way as in Example 1 with the exception that the amount of α-methylstyrene was set as 0.5329 g, the amount of cyclopentanone was set as 1.514 g, and a reaction was performed for 50 hours at a temperature of 30° C. in synthesis of the polymerized product and that the chemical composition (THF:MeOH (mass ratio)) of the mixed solvent used in purification of the polymerized product was set as 30:70. Various evaluations were performed in the same way as in Example 1. The results are shown in Table 1.

### Examples 12 to 15

Production of a copolymer, production of a positive resist composition, and formation of a resist pattern were performed in the same way as in Example 3 with the exception that the amount of α-methylstyrene was set as 1.066 g and the polymerization reaction temperature and time were set as 6 hours at 70° C. (Example 12), 6 hours at 60° C. (Example 13), 6 hours at 50° C. (Example 14), or 11 hours at 40° C. (Example 15) in synthesis of the polymerized product and that the chemical composition (THF:MeOH (mass ratio)) of the mixed solvent used in purification of the polymerized product was set as 30:70 (Example 12), 32:68 (Example 13), 34:66 (Example 14), or 34:66 (Example 15). Various evaluations were performed in the same way as in Example 1. The results are shown in Table 1.

### Example 16

Production of a copolymer, production of a positive resist composition, and formation of a resist pattern were performed in the same way as in Example with the exception that ethanol was used as a developer in formation of the resist pattern. Various evaluations were performed in the same way as in Example 1. The results are shown in Table 1.

### Example 17

Production of a copolymer, production of a positive resist composition, and formation of a resist pattern were performed in the same way as in Example 3 with the exception that 2-butanol (2-BtOH) was used as a developer in formation of the resist pattern. Various evaluations were performed in the same way as in Example 1. The results are shown in Table 1.

### Example 18

Production of a copolymer, production of a positive resist composition, and formation of a resist pattern were performed in the same way as in Example 9 with the exception that 2-butanol was used as a developer in formation of the resist pattern. Various evaluations were performed in the same way as in Example 1. The results are shown in Table 1.

### Example 19

Production of a copolymer, production of a positive resist composition, and formation of a resist pattern were performed in the same way as in Example with the exception that 2-butanol was used as a developer in formation of the resist pattern. Various evaluations were performed in the same way as in Example 1. The results are shown in Table 1.

### Example 20

Production of a copolymer, production of a positive resist composition, and formation of a resist pattern were performed in the same way as in Example 3 with the exception that the polymerization reaction temperature and time were set as 1 hour at 75° C. in synthesis of the polymerized product and that the chemical composition (THF:MeOH (mass ratio)) of the mixed solvent used in purification of the polymerized product was set as 30:70. Various evaluations were performed in the same way as in Example 1. The results are shown in Table 2.

### Example 21

Production of a copolymer, production of a positive resist composition, and formation of a resist pattern were performed in the same way as in Example with the exception that purification of the polymerized product was performed as described below. Various evaluations were performed in the same way as in Example 1. The results are shown in Table 2.

### [Purification of Polymerized Product]

The polymerized product that had been collected by filtration was dissolved in 10 g of tetrahydrofuran (THF) and then the resultant solution was dripped into 100 g of a mixed solvent of THF and methanol (MeOH) (THF:MeOH (mass ratio)=30:70) to cause precipitation of a white coagulated material. Next, the solution containing the coagulated material that had precipitated was filtered using a Kiriyama funnel, and the obtained white coagulated material was once again dissolved in 10 g of tetrahydrofuran (THF). The resultant solution was dripped into 100 g of a mixed solvent for repurification (THF:MeOH (mass ratio)=30:70) to cause precipitation (repurification) of a white recoagulated material (copolymer comprising α-methylstyrene units and 1-phenyl-1-trifluoromethyl-2,2,2-trifluoroethyl α-chloroacrylate units). Thereafter, the solution containing the precipitated copolymer was filtered using a Kiriyama funnel to obtain a white copolymer (copolymer comprising 50 mol % of α-methylstyrene units and 50 mol % of 1-phenyl-1-trifluoromethyl-2,2,2-trifluoroethyl α-chloroacrylate units).

### Examples 22 to 25

Production of a copolymer, production of a positive resist composition, and formation of a resist pattern were performed in the same way as in Example 21 with the exception that the chemical composition (THF:MeOH (mass ratio)) of the mixed solvent for repurification used in purification of the polymerized product was set as 31:39 (Example 22), 32:68 (Example 23), 33:67 (Example 24), or 34:66 (Example 25). Various evaluations were performed in the same way as in Example 1. The results are shown in Table 2.

### Example 26

Production of a copolymer, production of a positive resist composition, and formation of a resist pattern were performed in the same way as in Example with the exception that purification of the polymerized product was performed as described below. Various evaluations were performed in the same way as in Example 1. The results are shown in Table 2.

### [Purification of Polymerized Product]

The polymerized product that had been collected by filtration was dissolved in 10 g of tetrahydrofuran (THF) and then the resultant solution was dripped into 100 g of a mixed solvent of THF and methanol (MeOH) (THF:MeOH (mass ratio)=30:70) to cause precipitation of a white coagulated material. Next, the solution containing the coagulated material that had precipitated was filtered using a Kiriyama funnel, and the obtained white coagulated material was once again dissolved in 10 g of tetrahydrofuran (THF). The resultant solution was dripped into 100 g of a mixed solvent for repurification (THF:MeOH (mass ratio)=33:67) to cause precipitation (repurification) of a white recoagulated material. In addition, the solution containing the recoagulated material that had precipitated was filtered using a Kiriyama funnel, and the obtained white recoagulated material was once again dissolved in 10 g of tetrahydrofuran (THF). The resultant solution was dripped into 100 g of a mixed solvent for further repurification (THF:MeOH (mass ratio)=33:67) to cause precipitation (further repurification) of a white further recoagulated material (copolymer comprising α-methylstyrene units and 1-phenyl-1-trifluoromethyl-2,2,2-trifluoroethyl α-chloroacrylate units). Thereafter, the solution containing the precipitated copolymer was filtered using a Kiriyama funnel to obtain a white copolymer (copolymer comprising 50 mol % of α-methylstyrene units and 50 mol % of 1-phenyl-1-trifluoromethyl-2,2,2-trifluoroethyl α-chloroacrylate units).

### Examples 27 to 33

Production of a copolymer, production of a positive resist composition, and formation of a resist pattern were performed in the same way as in each of Examples 20 to 26 with the exception that the amount of α-methylstyrene was set as 1.066 g in synthesis of the polymerized product. Various evaluations were performed in the same way as in Example 1. The results are shown in Table 2.

### Comparative Example 1

Production of a copolymer, production of a positive resist composition, and formation of a resist pattern were performed in the same way as in Example 1 with the exception that 0.003953 g of azobisisobutyronitrile was added to the monomer composition as a polymerization initiator, cyclopentanone was not used, and a reaction was performed for 3.5 hours at 78° C. in synthesis of the polymerized product and that purification of the polymerized product was not performed. Various evaluations were performed in the same way as in Example 1. The results are shown in Table 3.

### Comparative Example 2

Production of a copolymer, production of a positive resist composition, and formation of a resist pattern were performed in the same way as in Example 1 with the exception that 0.003953 g of azobisisobutyronitrile was added to the monomer composition as a polymerization initiator, cyclopentanone was not used, and a reaction was performed for 3.5 hours at 78° C. in synthesis of the polymerized product and that the chemical composition (THF:MeOH (mass ratio)) of the mixed solvent used in purification of the polymerized product was set as 20:80. Various evaluations were performed in the same way as in Example 1. The results are shown in Table 3.

### Comparative Example 3

Production of a copolymer, production of a positive resist composition, and formation of a resist pattern were performed in the same way as in Example 1 with the exception that production of the copolymer and formation of the resist pattern were performed as described below. Various evaluations were performed in the same way as in Example 1. The results are shown in Table 3.

### <Production of Copolymer>

### [Synthesis of Polymerized Product]

A glass ampoule in which a stirrer had been placed was charged with a monomer composition containing 3.00 g of pentafluoropropyl α-chloroacrylate as a monomer, 3.476 g of α-methylstyrene as a monomer (b), 0.005513 g of azobisisobutyronitrile as a polymerization initiator, and 1.620 g of cyclopentanone as a solvent. The ampoule was tightly sealed and oxygen was removed from the system through 10 repetitions of pressurization and depressurization with nitrogen gas.

The system was then heated to 78° C. and a reaction was carried out for 6 hours. Next, 10 g of tetrahydrofuran was added to the system and then the resultant solution was dripped into 300 mL of methanol to cause precipitation of a polymerized product. Thereafter, the polymerized product that had precipitated was collected by filtration. Note that the obtained polymerized product was a copolymer comprising 50 mol % of α-methylstyrene units and 50 mol % of pentafluoropropyl α-chloroacrylate units.

### [Purification of Polymerized Product]

The polymerized product that had been collected by filtration was subsequently dissolved in 10 g of tetrahydrofuran (THF) and then the resultant solution was dripped into 100 g of a mixed solvent of THF and methanol (MeOH) (THF:MeOH (mass ratio)=15:85) to cause precipitation of a white coagulated material (copolymer comprising α-methylstyrene units and pentafluoropropyl α-chloroacrylate units). Thereafter, the solution containing the precipitated copolymer was filtered using a Kiriyama funnel to obtain a white copolymer (copolymer comprising 50 mol % of α-methylstyrene units and 50 mol % of pentafluoropropyl α-chloroacrylate units (ACAPFP units)).

### <Formation of Resist Pattern>

A spin coater (MS-A150 produced by Mikasa Co., Ltd.) was used to apply AL412 (produced by Brewer Science, Inc.) as a lower layer film onto a silicon wafer of 4 inches in diameter. The applied AL412 was heated for 1 minute by a hot plate having a temperature of 205° C. to form a lower layer film of 20 nm in thickness on the silicon wafer. Thereafter, the positive resist composition that had been obtained was applied onto this lower layer film. The applied positive resist composition was heated for 3 minutes by a hot plate having a temperature of 150° C. to form a resist film of 33 nm or 50 nm in thickness on the silicon wafer. The resist film was then exposed with the optimal exposure dose (Eₒₚ) using an EUV lithography tool (TWINSCAN NXE:3400B produced by ASML) to write a pattern. A hydrofluorocarbon (HFC; Vertrel XF (CF₃CFHCFHCF₂CF₃) produced by Mitsui-DuPont Fluorochemical Co., Ltd.) was then used as a developer to perform 30 seconds of development treatment at a temperature of 23° C. Next, a hydrofluoroether (HFE; Novec® 7100 (C₄F₉OCH₃) (Novec is a registered trademark in Japan, other countries, or both) produced by 3M) was used as a rinsing liquid to perform 10 seconds of rinsing at a temperature of 23° C. to form a resist pattern. Lines (non-exposed regions) and spaces (exposed regions) of the resist pattern were set as lines and spaces of 16 nm each (i.e., the half-pitch (hp) was 16 nm).

### Comparative Examples 4 to 6

Production of a copolymer, production of a positive resist composition, and formation of a resist pattern were performed in the same way as in Comparative Example 3 with the exception that the amount of α-methylstyrene was set as 3.283 g (Comparative Example 4), 3.468 g (Comparative Example 5), or 3.468 g (Comparative Example 6), the amount of azobisisobutyronitrile was set as 0.0005207 g (Comparative Example 4), 0.002065 g (Comparative Example 5), or 0.001377 g (Comparative Example 6), the amount of cyclopentanone was set as 1.571 g (Comparative Example 4), 6.466 g (Comparative Example 5), or 6.467 g (Comparative Example 6), and the polymerization reaction temperature and time were set as 2 hours at 78° C. (Comparative Example 4), 50 hours at 53° C. (Comparative Example 5), or 50 hours at 40° C. (Comparative Example 6) in synthesis of the polymerized product and that the chemical composition (THF:MeOH (mass ratio)) of the mixed solvent used in purification of the polymerized product was set as 21:79 (Comparative Example 4), 24:76 (Comparative Example 5), or 26:74 (Comparative Example 6). Various evaluations were performed in the same way as in Example 1. The results are shown in Table 3.

### Comparative Example 7

Production of a copolymer, production of a positive resist composition, and formation of a resist pattern were performed in the same way as in Example 1 with the exception that 0.003953 g of azobisisobutyronitrile was added to the monomer composition as a polymerization initiator, the amount of cyclopentanone was set as 1.380 g, and a reaction was performed for 6 hours at 78° C. in synthesis of the polymerized product and that purification of the polymerized product was not performed. Various evaluations were performed in the same way as in Example 1. The results are shown in Table 3.

TABLE 1

| | | | Example | Example | Example | Example | Example | Example | Example |
|---|---|---|---|---|---|---|---|---|---|
| | | | 1 | 2 | 3 | 4 | 5 | 6 | 7 |
| Copolymer | Chemical | ACAFPh units | 50 | 50 | 50 | 50 | 50 | 50 | 51 |
| | composition | [mol %] | | | | | | | |
| | | ACAPFP units | — | — | — | — | — | — | — |
| | | [mol %] | | | | | | | |
| | | AMS units | 50 | 50 | 50 | 50 | — | — | 49 |
| | | [mol %] | | | | | | | |
| | | 4-Methyl-AMS | — | — | — | — | 50 | 50 | — |
| | | units [mol %] | | | | | | | |
| | Weight-average molecular | | 116948 | 186495 | 481316 | 481316 | 262929 | 412509 | 175676 |
| | weight [−] | | | | | | | | |
| | Number-average molecular | | 76637 | 116305 | 287802 | 287802 | 151989 | 225278 | 115500 |
| | weight [−] | | | | | | | | |
| | Molecular weight | | 1.526 | 1.603 | 1.672 | 1.672 | 1.730 | 1.831 | 1.521 |
| | distribution [−] | | | | | | | | |
| | Components having | | 0.098 | 1.215 | 0.000 | 0.000 | 0.070 | 0.739 | 0.212 |
| | molecular weight of less | | | | | | | | |
| | than 10,000 [%] | | | | | | | | |
| | Components having | | 15.52 | 6.38 | 0.29 | 0.29 | 2.47 | 2.37 | 2.67 |
| | molecular weight of less | | | | | | | | |
| | than 50,000 [%] | | | | | | | | |
| | Components having | | 60.97 | 26.92 | 2.98 | 2.98 | 11.00 | 7.57 | 17.23 |
| | molecular weight of less | | | | | | | | |
| | than 100,000 [%] | | | | | | | | |
| | Components having | | 8.18 | 37.18 | 84.61 | 84.61 | 64.07 | 76.19 | 44.23 |
| | molecular weight of more | | | | | | | | |
| | than 200,000 [%] | | | | | | | | |
| Developer | | | IPA | IPA | IPA | EtOH | IPA | IPA | IPA |
| Evaluation | Thickness | Optimal | 60.1 | 64.4 | 67.0 | 50.3 | 65.0 | 70.1 | 63.4 |
| | 33 nm | exposure dose | | | | | | | |
| | | (Eop) [mJ/cm²] | | | | | | | |
| | | Half-pitch (hp) | 16 | 16 | 16 | 16 | 16 | 16 | 16 |
| | | [nm] | | | | | | | |
| | | CD [nm] | 16.2 | 16.3 | 16.0 | 16.0 | 15.9 | 15.9 | 16.0 |
| | | LWR [nm] | 4.7 | 4.4 | 4.3 | 4.7 | 4.1 | 4.1 | 4.3 |
| | | LER [nm] | 2.9 | 2.8 | 2.6 | 2.9 | 2.7 | 2.5 | 2.6 |
| | Thickness | Optimal | 45.7 | 46.7 | 56.0 | 42.0 | 51.0 | 55.4 | 46.6 |
| | 50 nm | exposure dose | | | | | | | |
| | | (Eop) [mJ/cm²] | | | | | | | |
| | | Contact hole | 22 | 22 | 22 | 22 | 22 | 22 | 22 |
| | | (CH) [nm] | | | | | | | |
| | | CD [nm] | 22.0 | 22.1 | 21.8 | 22.1 | 21.6 | 21.8 | 22.1 |
| | | LCDU [nm] | 3.8 | 3.7 | 3.5 | 3.7 | 3.5 | 3.4 | 3.6 |
| | | | Example | Example | Example | Example | Example | Example | Example |
| | | | 8 | 9 | 10 | 11 | 12 | 13 | 14 |
| Copolymer | Chemical | ACAFPh units | 52 | 54 | 54 | 55 | 54 | 54 | 54 |
| | composition | [mol %] | | | | | | | |
| | | ACAPFP units | — | — | — | — | — | — | — |
| | | [mol %] | | | | | | | |
| | | AMS units | 48 | 46 | 46 | 45 | 46 | 46 | 46 |
| | | [mol %] | | | | | | | |
| | | 4-Methyl-AMS | — | — | — | — | — | — | — |
| | | units [mol %] | | | | | | | |
| | Weight-average molecular | | 179823 | 188134 | 188134 | 188293 | 228370 | 306173 | 359721 |
| | weight [−] | | | | | | | | |
| | Number-average molecular | | 119009 | 125207 | 125207 | 124286 | 147149 | 198675 | 236953 |
| | weight [−] | | | | | | | | |
| | Molecular weight | | 1.511 | 1.503 | 1.503 | 1.515 | 1.552 | 1.541 | 1.518 |
| | distribution [−] | | | | | | | | |
| | Components having | | 0.345 | 0.315 | 0.315 | 0.301 | 0.001 | 0.005 | 0.000 |
| | molecular weight of less | | | | | | | | |
| | than 10,000 [%] | | | | | | | | |
| | Components having | | 2.65 | 2.65 | 2.65 | 2.55 | 0.58 | 0.42 | 0.12 |
| | molecular weight of less | | | | | | | | |
| | than 50,000 [%] | | | | | | | | |
| | Components having | | 16.88 | 16.62 | 16.62 | 16.59 | 4.31 | 2.41 | 1.62 |
| | molecular weight of less | | | | | | | | |
| | than 100,000 [%] | | | | | | | | |
| | Components having | | 45.53 | 46.24 | 46.24 | 46.36 | 73.29 | 85.92 | 90.88 |
| | molecular weight of more | | | | | | | | |
| | than 200,000 [%] | | | | | | | | |
| Developer | | | IPA | IPA | EtOH | IPA | IPA | IPA | IPA |
| Evaluation | Thickness | Optimal | 62.9 | 62.3 | 46.7 | 62.0 | 63.4 | 65.3 | 66.1 |
| | 33 nm | exposure dose | | | | | | | |
| | | (Eop) [mJ/cm²] | | | | | | | |
| | | Half-pitch (hp) | 16 | 16 | 16 | 16 | 16 | 16 | 16 |
| | | [nm] | | | | | | | |
| | | CD [nm] | 16.0 | 16.0 | 16.0 | 16.0 | 16.0 | 16.0 | 16.0 |
| | | LWR [nm] | 4.2 | 4.0 | 4.7 | 4.0 | 3.9 | 3.9 | 3.9 |
| | | LER [nm] | 2.6 | 2.5 | 3.0 | 2.4 | 2.4 | 2.4 | 2.4 |
| | Thickness | Optimal | 45.4 | 45.0 | 33.8 | 44.9 | 48.2 | 50.4 | 53.4 |
| | 50 nm | exposure dose | | | | | | | |
| | | (Eop) [mJ/cm²] | | | | | | | |
| | | Contact hole | 22 | 22 | 22 | 22 | 22 | 22 | 22 |
| | | (CH) [nm] | | | | | | | |
| | | CD [nm] | 22.2 | 22.2 | 22.1 | 22.1 | 22.3 | 22.1 | 22.0 |
| | | LCDU [nm] | 3.5 | 3.4 | 3.8 | 3.4 | 3.4 | 3.4 | 3.3 |

| | | | Example | Example | Example | Example | Example |
|---|---|---|---|---|---|---|---|
| | | | 15 | 16 | 17 | 18 | 19 |
| Copolymer | Chemical | ACAFPh units | 54 | 54 | 50 | 54 | 54 |
| | composition | [mol %] | | | | | |
| | | ACAPFP units | — | — | — | — | — |
| | | [mol %] | | | | | |
| | | AMS units | 46 | 46 | 50 | 46 | 46 |
| | | [mol %] | | | | | |
| | | 4-Methyl-AMS | — | — | — | — | — |
| | | units [mol %] | | | | | |
| | Weight-average molecular | | 395859 | 395859 | 481316 | 188134 | 395859 |
| | weight [−] | | | | | | |
| | Number-average molecular | | 246433 | 246433 | 287802 | 125207 | 246433 |
| | weight [−] | | | | | | |
| | Molecular weight | | 1.606 | 1.606 | 1.672 | 1.503 | 1.606 |
| | distribution [−] | | | | | | |
| | Components having | | 0.979 | 0.979 | 0.000 | 0.315 | 0.979 |
| | molecular weight of less | | | | | | |
| | than 10,000 [%] | | | | | | |
| | Components having | | 6.14 | 6.14 | 0.29 | 2.65 | 6.14 |
| | molecular weight of less | | | | | | |
| | than 50,000 [%] | | | | | | |
| | Components having | | 15.83 | 15.83 | 2.98 | 16.62 | 15.83 |
| | molecular weight of less | | | | | | |
| | than 100,000 [%] | | | | | | |
| | Components having | | 65.10 | 65.10 | 84.61 | 46.24 | 65.10 |
| | molecular weight of more | | | | | | |
| | than 200,000 [%] | | | | | | |
| Developer | | | IPA | EtOH | 2-BtOH | 2-BtOH | 2-BtOH |
| Evaluation | Thickness | Optimal | 67.0 | 50.3 | 70.4 | 65.4 | 70.4 |
| | 33 nm | exposure dose | | | | | |
| | | (Eop) [mJ/cm²] | | | | | |
| | | Half-pitch (hp) | 16 | 16 | 16 | 16 | 16 |
| | | [nm] | | | | | |
| | | CD [nm] | 16.0 | 16.0 | 16.0 | 16.0 | 16.0 |
| | | LWR [nm] | 3.8 | 4.5 | 4.3 | 4.0 | 3.8 |
| | | LER [nm] | 2.3 | 2.8 | 2.5 | 2.4 | 2.2 |
| | Thickness | Optimal | 56.0 | 42.0 | 53.6 | 47.3 | 58.8 |
| | 50 nm | exposure dose | | | | | |
| | | (Eop) [mJ/cm²] | | | | | |
| | | Contact hole | 22 | 22 | 22 | 22 | 22 |
| | | (CH) [nm] | | | | | |
| | | CD [nm] | 22.4 | 22.1 | 22.1 | 22.0 | 22.1 |
| | | LCDU [nm] | 3.3 | 3.6 | 3.4 | 3.3 | 3.3 |

TABLE 2

| | | | Example | Example | Example | Example | Example | Example | Example |
|---|---|---|---|---|---|---|---|---|---|
| | | | 20 | 21 | 22 | 23 | 24 | 25 | 26 |
| Copolymer | Chemical | ACAFPh units [mol %] | 50 | 50 | 50 | 50 | 50 | 50 | 50 |
| | composition | ACAPFP units [mol %] | — | — | — | — | — | — | — |
| | | AMS units [mol %] | 50 | 50 | 50 | 50 | 50 | 50 | 50 |
| | | 4-Methyl-AMS units | — | — | — | — | — | — | — |
| | | [mol %] | | | | | | | |
| | Weight-average molecular | | 242345 | 278394 | 283124 | 301920 | 320345 | 398450 | 389495 |
| | weight [−] | | | | | | | | |
| | Number-average molecular | | 153870 | 187977 | 193788 | 207505 | 220775 | 269401 | 286183 |
| | weight [−] | | | | | | | | |
| | Molecular weight distribution | | 1.575 | 1.481 | 1.461 | 1.455 | 1.451 | 1.481 | 1.361 |
| | [−] | | | | | | | | |
| | Components having molecular | | 0.211 | 0.000 | 0.091 | 0.140 | 0.102 | 0.092 | 0.000 |
| | weight of less than 10,000 [%] | | | | | | | | |
| | Components having molecular | | 2.45 | 0.43 | 0.63 | 0.69 | 0.60 | 0.51 | 0.09 |
| | weight of less than 50,000 [%] | | | | | | | | |
| | Components having molecular | | 14.21 | 6.32 | 3.94 | 3.90 | 2.94 | 2.65 | 1.31 |
| | weight of less than 100,000 [%] | | | | | | | | |
| | Components having molecular | | 59.65 | 69.54 | 73.21 | 75.43 | 80.32 | 89.43 | 92.34 |
| | weight of more than 200,000 | | | | | | | | |
| | [%] | | | | | | | | |
| Developer | | | IPA | IPA | IPA | IPA | IPA | IPA | IPA |
| Evaluation | Thickness | Optimal exposure | 65.0 | 65.2 | 65.5 | 65.7 | 66.1 | 67.1 | 66.3 |
| | 33 nm | dose (Eop) [mJ/cm²] | | | | | | | |
| | | Half-pitch (hp) [nm] | | 16 | 16 | 16 | 16 | 16 | 16 |
| | | CD [nm] | 16.2 | 16.0 | 16.0 | 16.0 | 16.0 | 16.1 | 16.0 |
| | | LWR [nm] | 4.4 | 3.9 | 3.8 | 3.7 | 3.6 | 3.8 | 3.4 |
| | | LER [nm] | 2.8 | 2.5 | 2.4 | 2.4 | 2.3 | 2.5 | 2.1 |
| | Thickness | Optimal exposure | 48.8 | 48.9 | 49.2 | 49.4 | 49.8 | 49.5 | 49.3 |
| | 50 nm | dose (Eop) [mJ/cm²] | | | | | | | |
| | | Contact hole (CH) | 22 | 22 | 22 | 22 | 22 | 22 | 22 |
| | | [nm] | | | | | | | |
| | | CD [nm] | 22.2 | 22.3 | 22.2 | 22.2 | 22.1 | 21.9 | 22.0 |
| | | LCDU [nm] | 3.6 | 3.3 | 3.2 | 3.2 | 3.2 | 3.3 | 3.1 |
| | | | Example | Example | Example | Example | Example | Example | Example |
| | | | 27 | 28 | 29 | 30 | 31 | 32 | 33 |
| Copolymer | Chemical | ACAFPh units [mol %] | 54 | 54 | 54 | 54 | 54 | 54 | 54 |
| | composition | ACAPFP units [mol %] | — | — | — | — | — | — | — |
| | | AMS units [mol %] | 46 | 46 | 46 | 46 | 46 | 46 | 46 |
| | | 4-Methyl-AMS units | — | — | — | — | — | — | — |
| | | [mol %] | | | | | | | |
| | Weight-average molecular | | 228370 | 257007 | 272064 | 287738 | 309236 | 382253 | 363867 |
| | weight [−] | | | | | | | | |
| | Number-average molecular | | 147149 | 174812 | 187210 | 199820 | 217154 | 259380 | 267588 |
| | weight [−] | | | | | | | | |
| | Molecular weight distribution | | 1.552 | 1.470 | 1.453 | 1.440 | 1.424 | 1.474 | 1.360 |
| | [−] | | | | | | | | |
| | Components having molecular | | 0.226 | 0.000 | 0.194 | 0.230 | 0.122 | 0.111 | 0.000 |
| | weight of less than 10,000 [%] | | | | | | | | |
| | Components having molecular | | 2.73 | 0.49 | 0.81 | 0.80 | 0.67 | 0.58 | 0.10 |
| | weight of less than 50,000 [%] | | | | | | | | |
| | Components having molecular | | 16.05 | 6.32 | 5.47 | 4.60 | 3.80 | 3.12 | 1.69 |
| | weight of less than 100,000 [%] | | | | | | | | |
| | Components having molecular | | 52.82 | 63.12 | 67.58 | 72.34 | 77.58 | 85.24 | 87.68 |
| | weight of more than 200,000 | | | | | | | | |
| | [%] | | | | | | | | |
| Developer | | | IPA | IPA | IPA | IPA | IPA | IPA | IPA |
| Evaluation | Thickness | Optimal exposure | 61.9 | 62.3 | 62.5 | 63.0 | 63.2 | 64.6 | 63.3 |
| | 33 nm | dose (Eop) [mJ/cm²] | | | | | | | |
| | | Half-pitch (hp) [nm] | 16 | 16 | 16 | 16 | 16 | 16 | 16 |
| | | CD [nm] | 16.0 | 16.1 | 15.9 | 16.1 | 16.0 | 16.2 | 16.0 |
| | | LWR [nm] | 4.0 | 3.7 | 3.6 | 3.5 | 3.5 | 3.6 | 3.3 |
| | | LER [nm] | 2.5 | 2.3 | 2.4 | 2.3 | 2.2 | 2.3 | 2.1 |
| | Thickness | Optimal exposure | 48.3 | 48.4 | 48.6 | 48.7 | 48.8 | 49.4 | 48.9 |
| | 50 nm | dose (Eop) [mJ/cm²] | | | | | | | |
| | | Contact hole (CH) | 22 | 22 | 22 | 22 | 22 | 22 | 22 |
| | | [nm] | | | | | | | |
| | | CD [nm] | 22.3 | 22.1 | 22.2 | 22.3 | 22.1 | 21.9 | 22.0 |
| | | LCDU [nm] | 3.4 | 3.2 | 3.2 | 3.1 | 3.1 | 3.2 | 2.9 |

TABLE 3

| | | | Comparative | Comparative | Comparative | Comparative | Comparative | Comparative | Comparative |
|---|---|---|---|---|---|---|---|---|---|
| | | | Example 1 | Example 2 | Example 3 | Example 4 | Example 5 | Example 6 | Example 7 |
| Copolymer | Chemical | ACAFPh units | 50 | 50 | — | — | — | — | 50 |
| | composition | [mol %] | | | | | | | |
| | | ACAPFP units | — | — | 50 | 50 | 50 | 50 | — |
| | | [mol %] | | | | | | | |
| | | AMS units | 50 | 50 | 50 | 50 | 50 | 50 | 50 |
| | | [mol %] | | | | | | | |
| | | 4-Methyl-AMS | — | — | — | — | — | — | — |
| | | units [mol %] | | | | | | | |
| | Weight-average molecular | | 48923 | 56532 | 49556 | 85192 | 130365 | 180605 | 35200 |
| | weight [−] | | | | | | | | |
| | Number-average molecular | | 27454 | 39727 | 35806 | 59952 | 92392 | 128728 | 23451 |
| | weight [−] | | | | | | | | |
| | Molecular weight distribution | | 1.782 | 1.423 | 1.384 | 1.421 | 1.411 | 1.403 | 1.501 |
| | [−] | | | | | | | | |
| | Components having molecular | | 3.563 | 1.597 | 0.512 | 0.414 | 0.133 | 0.040 | 13.560 |
| | weight of less than 10,000 [%] | | | | | | | | |
| | Components having molecular | | 51.54 | 39.14 | 62.67 | 32.64 | 10.61 | 6.69 | 82.34 |
| | weight of less than 50,000 [%] | | | | | | | | |
| | Components having molecular | | 85.35 | 78.42 | 93.06 | 78.30 | 52.05 | 29.90 | 98.32 |
| | weight of less than 100,000 [%] | | | | | | | | |
| | Components having molecular | | 1.84 | 4.09 | 0.50 | 3.23 | 10.40 | 22.78 | 0.00 |
| | weight of more than 200,000 | | | | | | | | |
| | [%] | | | | | | | | |
| Devebper | | | IPA | IPA | HFC | HFC | HFC | HFC | IPA |
| Evaluation | Thickness | Optimal | 48.4 | 51.2 | 56.6 | 54.3 | 40.1 | 47.0 | 47.1 |
| | 33 nm | exposure dose | | | | | | | |
| | | (Eop) [mJ/cm²] | | | | | | | |
| | | Half-pitch (hp) | 16 | 16 | 16 | 16 | 16 | 16 | 16 |
| | | [nm] | | | | | | | |
| | | CD [nm] | 16.2 | 16.1 | 16.2 | 16.1 | 16.2 | 15.9 | 15.9 |
| | | LWR [nm] | 7.4 | 6.9 | 8.3 | 7.7 | 6.2 | 5.4 | 8.4 |
| | | LER [nm] | 4.7 | 3.9 | 5.3 | 4.9 | 4.0 | 3.4 | 5.6 |
| | Thickness | Optimal | 48.4 | 50.4 | 58.6 | 48.5 | 48.6 | 42.4 | 49.1 |
| | 50 nm | exposure dose | | | | | | | |
| | | (Eop) | | | | | | | |
| | | [mJ/cm²] | | | | | | | |
| | | Contact hole | 22 | 22 | 22 | 22 | 22 | 22 | 22 |
| | | (CH) [nm] | | | | | | | |
| | | CD [um] | 22.3 | 22.1 | 22.1 | 22.1 | 22.1 | 22.0 | 22.0 |
| | | LCDU [mm] | 4.8 | 4.5 | 5.0 | 4.9 | 4.9 | 4.8 | 5.3 |

It can be seen from Tables 1 to 3 that it was possible to efficiently form a fine resist pattern with high resolution in Examples 1 to 33 compared to in Comparative Examples 1 to 7.

### INDUSTRIAL APPLICABILITY

According to the present disclosure, it is possible to efficiently form a fine resist pattern with high resolution in an EUV lithography technique.

1. A positive resist composition for extreme ultraviolet lithography comprising a copolymer that has a weight-average molecular weight of more than 100,000 and that includes:
a monomer unit (A) represented by formula (I), shown below, 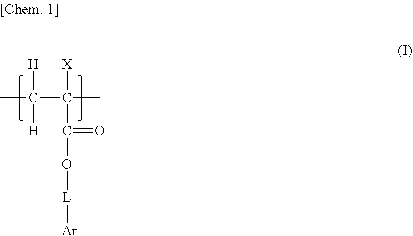
where, in formula (I), X is a halogen atom, a cyano group, an alkylsulfonyl group, an alkoxy group, a nitro group, an acyl group, an alkyl ester group, or a haloalkyl group, L is a single bond or a divalent linking group, and Ar is an optionally substituted aromatic ring group; and
a monomer unit (B) represented by formula (II), shown below, 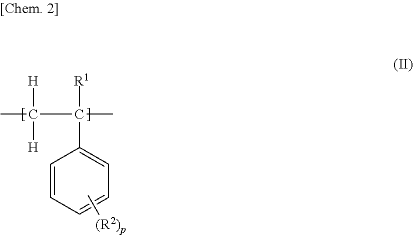
where, in formula (II), R¹ is an alkyl group, R² is an alkyl group, a halogen atom, a haloalkyl group, a hydroxyl group, a carboxyl group, or a halogenated carboxyl group, p is an integer of not less than 0 and not more than 5, and in a case in which more than one R² is present, each R² may be the same or different.

2. The positive resist composition for extreme ultraviolet lithography according to claim 1, wherein
the monomer unit (A) is a 1-phenyl-1-trifluoromethyl-2,2,2-trifluoroethyl α-chloroacrylate unit, and
the monomer unit (B) is an α-methylstyrene unit or a 4-methyl-α-methylstyrene unit.

3. The positive resist composition for extreme ultraviolet lithography according to claim 1, wherein proportional content of the monomer unit (A) in the copolymer is more than 50 mol % and not more than 60 mol %, and proportional content of the monomer unit (B) in the copolymer is not less than 40 mol % and less than 50 mol %.

4. The positive resist composition for extreme ultraviolet lithography according to claim 1, wherein the copolymer has a molecular weight distribution (Mw/Mn) of not less than 1.20 and not more than 1.60.

5. The positive resist composition for extreme ultraviolet lithography according to claim 1, wherein a proportion of components having a molecular weight of less than 10,000 in the copolymer is less than 1.5%.

6. The positive resist composition for extreme ultraviolet lithography according to claim 1, wherein a proportion of components having a molecular weight of less than 50,000 in the copolymer is less than 30%.

7. The positive resist composition for extreme ultraviolet lithography according to claim 1, wherein a proportion of components having a molecular weight of less than 100,000 in the copolymer is less than 70%.

8. The positive resist composition for extreme ultraviolet lithography according to claim 1, wherein a proportion of components having a molecular weight of more than 200,000 in the copolymer is more than 8.0%.

9. A resist pattern formation kit for extreme ultraviolet lithography comprising: the positive resist composition for extreme ultraviolet lithography according to claim 1; and a developer.

10. The resist pattern formation kit for extreme ultraviolet lithography according to claim 9, wherein the developer is an alcohol.

11. The resist pattern formation kit for extreme ultraviolet lithography according to claim 10, wherein the alcohol has a carbon number of not less than 2 and not more than 6.
